(19) United States
(12) Patent Application Publication
(10) Pub. No.: US 2025/0240940 A1
(43) Pub. Date: Jul. 24, 2025

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Yun-Feng KAO, Hsinchu (TW); Katherine H. CHIANG, Hsinchu (TW); Chien-Hao HUANG, Hsinchu (TW); Chih-Yu CHANG, Hsinchu (TW); Yen-Chung HO, Hsinchu (TW); Wai-Kit LEE, Hsinchu (TW); Yong-Jie WU, Hsinchu (TW); Chen-Jun WU, Hsinchu (TW)

(73) Assignee: Taiwan Semiconductor Manufacturing Company, Ltd., Hsinchu (TW)

(21) Appl. No.: 18/418,623

(22) Filed: Jan. 22, 2024

(51) Int. Cl. H10B 12/00

(52) U.S. Cl. CPC H10B 12/33; H10B 12/036; H10B 12/05

(57) ABSTRACT

A semiconductor device and a manufacturing method thereof are provided. The semiconductor device includes a substrate and a vertical transistor. The vertical transistor is disposed on the substrate. The vertical transistor comprises an insulating layer, a source, a drain, a gate insulating layer and a gate. The source and the drain are arranged below and above the insulating layer, and the gate insulating layer surrounds the insulating layer, the source and the drain. The gate covers the gate insulating layer, and the gate insulating layer separates the gate from the source and separates the gate from the drain.

### BACKGROUND

As the semiconductor industry introduces new generations of integrated circuits (IC) having higher performance and more functionality, the density of the elements forming the ICs increases, while the dimensions, sizes and spacing between components or elements are reduced. The semiconductor industry continues to improve the integration density of various electronic components (e.g., transistors, diodes, resistors, capacitors, etc.) by continual reductions in minimum feature size, which allow more components to be integrated into a given area.

In order to obtain memory cells with good data retention capabilities, long channel length is one of the approaches. However, in existing planar bottom/top gate structures, we have to pay more area costs to implement transistor devices with long channel.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic layout diagram of a semiconductor device according to an embodiment of the present disclosure.

FIG. 2A is a cross-sectional view of the semiconductor device in FIG. 1 along the direction X1-X1.

FIG. 2B is a cross-sectional view of the semiconductor device in FIG. 1 along the direction X2-X2.

FIG. 2C is a cross-sectional view of the semiconductor device in FIG. 1 along the direction Y-Y.

FIGS. 3A to 3H are schematic diagrams of a method of manufacturing the semiconductor device in FIG. 2A.

FIGS. 4A to 4C are respectively schematic diagrams of semiconductor devices according to another three embodiments of the present disclosure.

FIGS. 5A and 5B are respectively schematic diagrams of semiconductor devices according to another two embodiments of the present disclosure.

FIGS. 6A and 6B are respectively schematic layout diagrams of semiconductor devices according to two embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

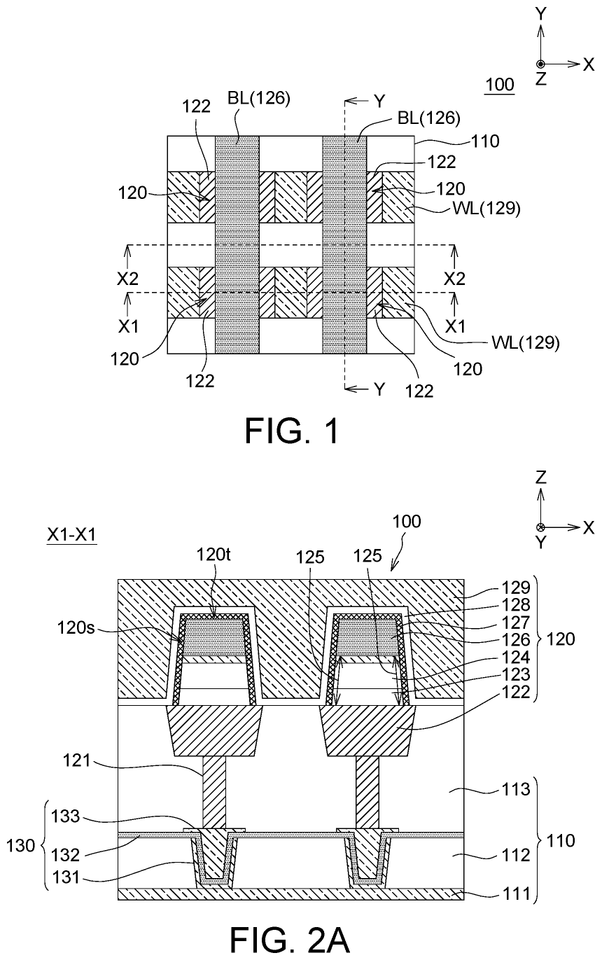

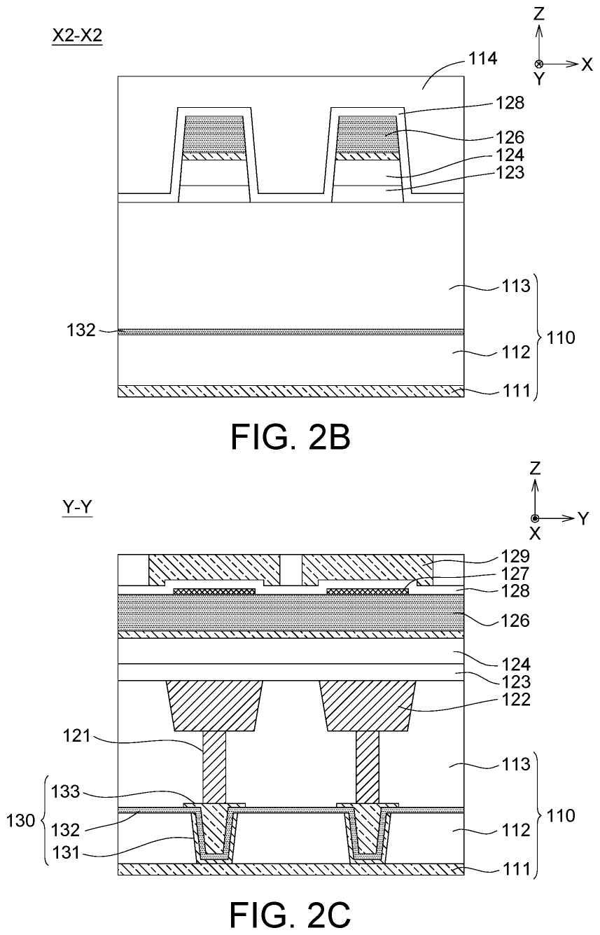

Referring to FIGS. 1, 2A, 2B, and 2C, FIG. 1 is a schematic layout diagram of a semiconductor device 100 according to an embodiment of the present disclosure, FIG. 2A is a cross-sectional view of the semiconductor device 100 in FIG. 1 along the direction X1-X1. FIG. 2B is a cross-sectional view of the semiconductor device 100 in FIG. 1 along the direction X2-X2, and FIG. 2C is a cross-sectional view of the semiconductor device 100 in FIG. 1 along the direction Y-Y. The semiconductor device 100 is, for example, a memory device. A common memory device is a dynamic random access memory (DRAM), which is used to store data.

The semiconductor device 100 includes a substrate 110, a vertical transistor 120, a capacitor 130, a bit line BL, a word line WL and a source line (not shown). The vertical transistor 120 and the capacitor 130 are disposed on or in the substrate 110. The bit line BL is electrically coupled to one end of the vertical transistor 120, the source 122 is electrically coupled to the other end of the vertical transistor 120, and the word line WL is coupled to the gate 129 of the vertical transistor 120. Therefore, when an appropriate voltage of word line WL is applied to the gate 129 of the vertical transistor 120, the voltage of the gate 129 of the vertical transistor 120 will be greater than a threshold voltage and allow a current to flow through the vertical transistor 120 between the bit line BL and the source 122, so that the vertical transistor 120 is turned on.

As shown in FIG. 2A, the substrate 110 includes a conductive layer 111, an insulating layer 112 and an interlayer dielectric layer 113 and/or an insulating layer 114 (see FIG. 2B). The interconnection structure in the substrate 110 is not limited to being directly formed on the semiconductor device 100. Other structures (e.g., middle-end-of-the-line (MEOL) structures) may be formed between the interconnection structure and the semiconductor device 100. Therefore, the interlayer dielectric layers of the interconnection structure may be two layers, three layers, or more. The insulating layers 112, 114 and the interlayer dielectric layer 113 can be formed by physical vapor deposition (PVD), chemical vapor deposition (CVD), atomic layer deposition (ALD), spin coating or other suitable processes. The layers 112-114 may include amorphous SiOx, SiOxCyHz, SiOxCy, SiCx, SiNx or related low-k value materials. The conductive layer 111 may include cobalt (Co), ruthenium (Ru), molybdenum (Mo), chromium (Cr), tungsten (W), manganese (Mn), rhodium (Rh), iridium (Ir), nickel (Ni), palladium (Pd), platinum (Pt), silver (Ag), gold (Au), aluminum (Al), copper (Cu) or alloys of the above, or other suitable materials.

As shown in FIG. 2A, the vertical transistor 120 includes an insulating layer 124, a source 122, a drain 126, a channel layer 127, a gate insulating layer 128 and a gate 129. The source 122 and the drain 126 are respectively disposed below and above the insulating layer 124, and the gate insulating layer 128 surrounds the insulating layer 124, the source 122 and the drain 126. In one embodiment, the insulating layer 124 may be silicon dioxide or other oxides, and the gate insulating layer 128 may be silicon dioxide or other oxides. The source 122 and the drain 126 may include one or more conductive materials, such as metals and/or semiconductor materials doped with doped with P type or N type dopant. The bit line BL may be electrically connected to the drain 126, or the drain 126 may serve as the bit line BL. In addition, the source line may be electrically connected to the source 122, or the source 122 may serve as a source line.

As shown in FIG. 2B, the cross-section view is made along the direction X2-X2, the gate insulating layer 128 surrounds the insulating layer 124 and the drain 126. However, since the channel layer 127 and the gate 129 are not formed in the area between two adjacent word lines WL, in FIG. 2B, only another insulation layer 114 is formed to cover the gate insulation layer 128. However, in another embodiment, the channel layer 127 of FIG. 2A can also be formed in the area between two adjacent word lines WL.

As shown in FIG. 2C, the cross-section view is made along the direction Y-Y, the drain 126 (bit line BL) and the insulating layer 124 pass through the two adjacent sources 122, and the gate insulating layer 128 covers the two channel layers 127 and drain 126 (bit line BL), and two gates 129 (word lines WL) correspondingly cover the two channel layers 127. However, in another embodiment, the two channel layers 127 can also be connected to each other.

In one embodiment, the source 122 and the drain 126 are formed by implanting appropriate dopants such as arsenic or boron on the top and bottom of a stacked structure 120′, and an insulating layer 124 is used in the implantation process to dispsoed between the source 122 and the drain 126. The formation of the source 122 and the drain 126 enables the vertical transistor 120 to become an NMOS device or a PMOS device in the vertical direction.

As shown in FIG. 2A, the channel layer 127 surrounds all sidewalls 120s and the top 120t of the insulating layer 124, the source 122 and the drain 126 and forms two sidewall channels 125 between the source 122 and the drain 126. The channel layer 127 is, for example, a semiconductor material, which allows a current to pass through the drain 126 and the source 122 of the vertical transistor 120 in a biased state. Since the two sidewall channels 125 are located in the vertical direction, the length of the two sidewall channels 125 can be increased without occupying the area in the lateral direction. In addition, the two sidewall channels 125 can increase the amount of driving current passing through the drain 126 and the source 122 of the vertical transistor 120 to increase the reading and writing speed of the semiconductor device 100.

As shown in FIG. 2A, the gate 129 covers the gate insulating layer 128, and the gate insulating layer 128 electrically isolates the gate 129 from the source 122 and electrically isolates the gate 129 from the drain 126. The gate 129 can be a metal electrode or other materials. The word line WL may be electrically connected to the gate 129, or the gate 129 may serve as the word line WL. The gate insulating layer 128 is preferably made of a high-k dielectric material, such as silicon oxide, silicon oxynitride, silicon nitride, oxide, nitrogen-containing oxide, combinations of the above materials, or the like. Preferably, the gate insulating layer 128 has a dielectric constant greater than 4. Alternatively, the materials of the gate insulating layer 128 may include, for example, one of aluminum oxide, lanthanum oxide, hafnium oxide, zirconium oxide, hafnium oxynitride, and combinations of the above materials.

In some embodiments, the gate 129 includes a conductive material, such as a metal (such as tantalum, titanium, molybdenum, tungsten, platinum, aluminum, hafnium, ruthenium), a metal silicide (such as titanium silicide, cobalt silicide, nickel silicide, tantalum silicide), a metal nitride (such as titanium nitride, tantalum nitride), doped polycrystalline silicon, other conductive materials, or a combination of the above materials. In one embodiment, amorphous silicon material may be deposited and then recrystallized to form polycrystalline silicon material. In a preferred embodiment, the gate 129 can be polycrystalline silicon, and the gate 129 can be formed by depositing doped or undoped polycrystalline silicon by a low-pressure chemical vapor deposition method to a thickness of between 400 and 2500 angstroms, and the thickness is preferably about 1500 angstroms.

As shown in FIG. 2A, a capacitor 130 is disposed in the substrate 110, and the capacitor 130 is electrically connected to the vertical transistor 120. In one embodiment, a conductive via 121 is disposed in the substrate 110, and the conductive via 121 can electrically connect the capacitor 130 and the vertical transistor 120. The source 122 of the vertical transistor 120 can be electrically coupled to the conductive via 121. When the vertical transistor 120 is turned on, carriers (such as holes or electrons) can flow to the source 122 from the drain 126 of the vertical transistor 120, and stores charges in capacitor 130.

As shown in FIG. 2A, the capacitor 130 includes two electrodes and a dielectric layer 132. The dielectric layer 132 is located between the two electrodes. The charges stored in the capacitor 130 is proportional to its potential. The capacitance is proportional to the area of the two electrodes and the dielectric coefficient of the dielectric layer 132, and is inversely proportional to the distance between the two electrodes.

The electrodes include a bottom electrode 131 and a top electrode 133. The bottom electrode 131 is preferably formed by depositing and patterning a layer of conductive material, such as titanium nitride, tantalum nitride or the like. The bottom electrode 131 can be formed by a chemical vapor deposition method and has a thickness of about 100 to 500 angstroms, preferably about 200 angstroms. The dielectric layer 132 and the top electrode 133 are preferably formed by depositing and patterning a layer of dielectric material and a conductive layer, respectively. The dielectric layer 132 preferably includes a high-k dielectric material, such as tantalum oxide, aluminum oxide, zirconium oxide, hafnium oxide, barium strontium titanate (BST), lead zirconium titanate (PZT), oxide, other multi-layer high-k dielectric materials, and the like. The dielectric layer 132 is preferably formed by chemical vapor deposition and has a thickness of about 15 to 200 angstroms, and preferably about 110 angstroms. The top electrode 133 preferably includes a conductive material such as silicon nitride, tantalum nitride, ruthenium, aluminum, tungsten, copper or the like, which can be formed by a chemical vapor deposition or the like. The top electrode 133 preferably has a thickness of about 100 to 500 angstroms, and more preferably has a thickness of 110 angstroms. It is worth noting that the capacitor 130 may have other shapes, types, or similar situations.

As shown in FIG. 2A, an etching stop layer 123 is formed between the source 122 and the insulating layer 124, but the etching stop layer 123 is not necessary. Preferably, the etch stop layer 123 has a thickness ranging from 300 to 1500 angstroms. The etch stop layer 123 may be made of materials such as nitride, oxynitride, oxide, silicon carbide, silicon oxycarbide, combinations of the above materials or the like.

The semiconductor device 100 of this disclosure includes a vertical transistor 120 and a capacitor 130 to form a memory unit (such as a dynamic random access memory), and the capacitance stored in the capacitor 130 represents a bit data. Since traditional transistors have leakage current, the capacitance stored in the capacitor 130 is not enough to correctly identify the bit data, resulting in data damage. Since the semiconductor device 100 of this embodiment uses the vertical transistor 120 with a longer channel length, which can further reduce leakage current and increase the number of transistors per unit area.

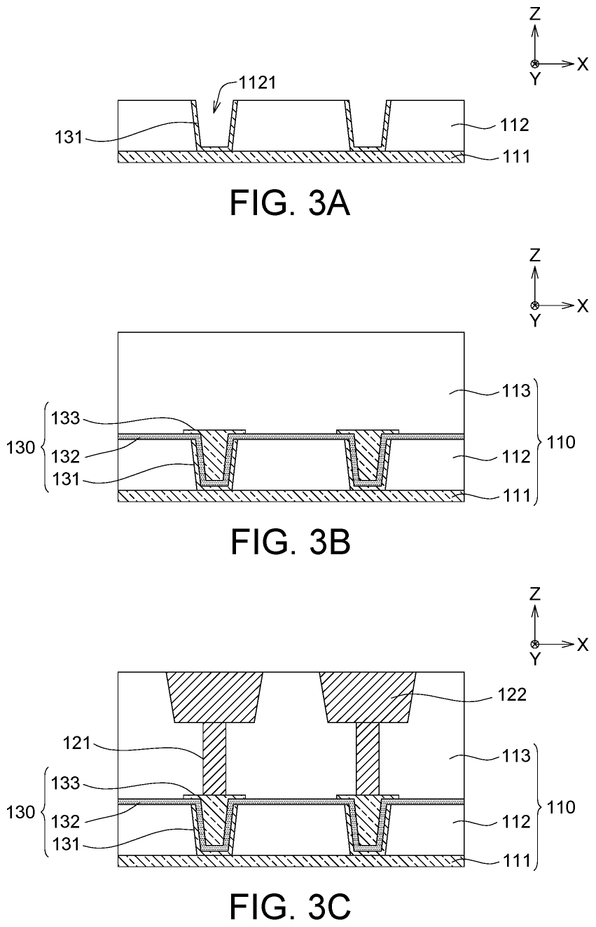

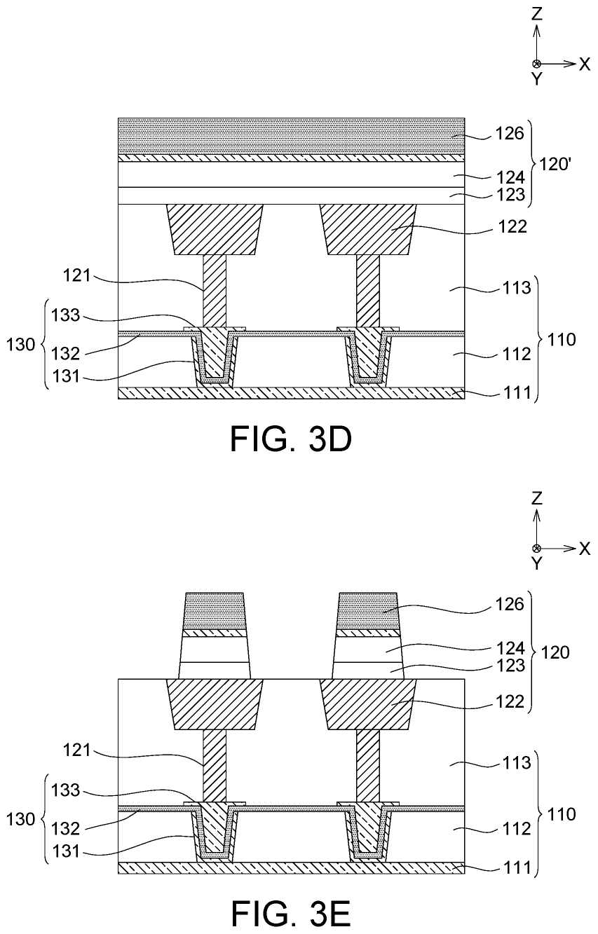

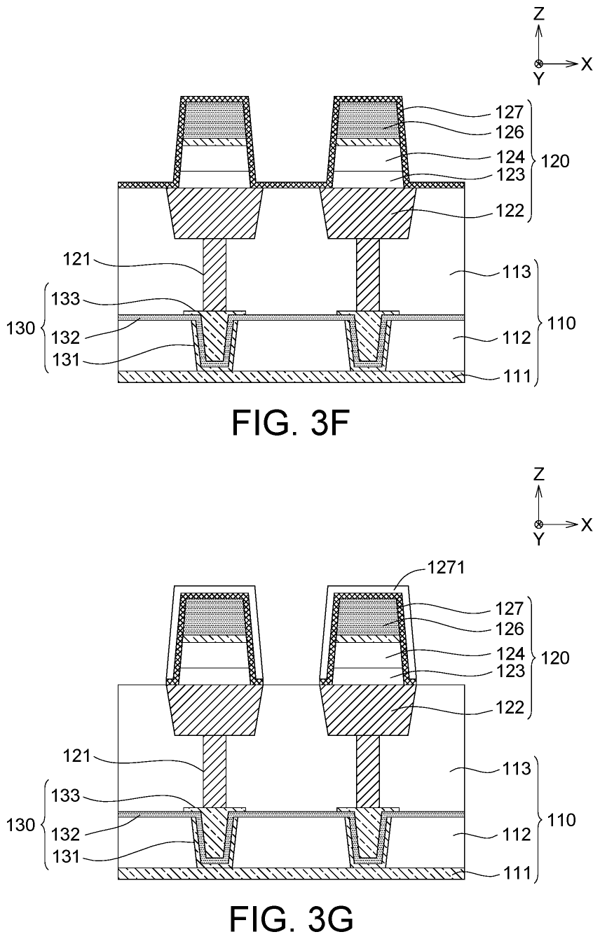

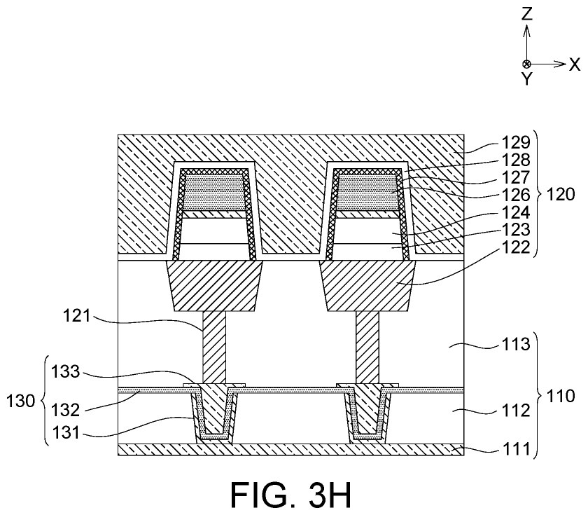

The following describes a method of manufacturing a semiconductor device 100. It can be understood that the operating steps shown in the manufacturing method are not exhaustive, and other operating steps can also be performed before, after or during any of the illustrated operating steps. Furthermore, some of the operational steps may be performed simultaneously or in an order different from that shown in FIGS. 3A to 3H.

Referring to FIGS. 3A to 3H, schematic diagrams of the method of manufacturing the semiconductor device 100 of FIG. 2A are illustrated. First, in FIG. 3A, an opening 1121 is formed in an insulating layer 112, for example, by etching the insulating layer 112 to remove part of the insulating layer 112 and forming an opening 1121 in the insulating layer 112. A conductive layer 111 is disposed below the insulating layer 112. A conductive metal is deposited above the conductive layer 111 and in the opening 1121 by physical vapor deposition (PVD), chemical vapor deposition (CVD), atomic layer deposition (ALD), spin coating or other suitable processes, and the excess conductive metal is removed through etching back to serve as a bottom electrode 131. The bottom electrode 131 may be formed by plasma etching, reactive ion etching (RIE), or other suitable processes. The bottom electrode 131 is, for example, a conductive via, which can be electrically connected to the conductive layer 111 under the interconnection structure.

Next, in FIG. 3B, a dielectric layer 132 and a top electrode 133 are formed. The dielectric layer 132 is located between the top electrode 133 and the bottom electrode 131 for electrical isolation. In some embodiments, a conductive metal is deposited above dielectric layer 132 and is partially etched to form the top electrode 133. The dielectric layer 132 and the top electrode 133 can be formed by physical vapor deposition (PVD), chemical vapor deposition (CVD), atomic layer deposition (ALD), spin coating or other suitable processes.

Next, in FIG. 3C, a conductive via 121 and a source 122 are formed in the interlayered dielectric layer 113, and the conductive via 121 is electrically coupled to the source 122 and the top electrode 133 of the capacitor 130 so that the current can flow between the source 122 and the capacitor 130.

Next, in FIG. 3D, a stacked structure 120′ is formed on a substrate 110. The stacked structure 120′ may include an etching stop layer 123, an insulating layer 124 and a drain 126. The etching stop layer 123, the insulating layer 124 and the drain 126 are formed, for example, by chemical vapor deposition, physical vapor deposition or other methods. Next, in FIG. 3E, the stacked structure 120′ is etched to form at least one vertical column structure (two are shown in the figures). The vertical structure is correspondingly located above the source 122, or the vertical structure may also include the source 122. In this embodiment, the source 122 and the drain 126 are disposed below and above the insulating layer 124 to serve as the source 122 and the drain 126 of a vertical transistor 120.

In FIG. 3F, a channel layer 127 is deposited over the vertical transistor 120 in FIG. 3E. The channel layer 127 surrounds the sidewalls of the insulating layer 124 and the drain 126 and is disposed on the source 122 to form two sidewall channels 125 between the source 122 and the drain 126. The length of the two sidewall channels 125 depends on the thickness of the insulating layer 124. As the thickness of the insulating layer 124 increases, the length of the two sidewall channels 125 also increases accordingly. Therefore, the two sidewall channels 125 of the vertical transistor 120 can provide sufficient channel length to reduce leakage current. The material of the channel layer 127 may be indium zinc oxide (InZnO), indium tin oxide (ITO), Indium oxide (In₂O₃), Ga₂O₃, InGaZnO, ZnO, Al₂O₅Zn₂, aluminum-doped ZnO, IWO, TiOx or semiconductor materials comprising other III-V materials, combinations (e.g., alloys or stacked layers) of above semiconductor materials.

Next, in FIG. 3G, a part of the channel layer 127 is etched. For example, a sacrificial oxide 1271 is deposited over the channel layer 127 and used as a mask to cover the channel layer 127, a part of the channel layer 127 is removed by etching, and the remaining part of the channel layer 127 surrounds the insulating layer 124 and the drain 126. Next, in FIG. 3H, after the sacrificial oxide 1271 is removed, a gate insulating layer 128 is formed around the channel layer 127, and a gate 129 is formed to cover the gate insulating layer 128. The gate insulating layer 128 separates the gate 129 from the source 122 and separates the gate 129 from the drain 126.

In order to obtain a minimum-sized memory cell in the traditional semiconductor device, the channel length of the traditional transistor must be shortened as much as possible to reduce the lateral area of the memory cell. However, this will make the gate unable to tolerate excessive leakage current and the voltage on the bit line must be reduced accordingly, thereby reducing the capacitance stored in the capacitor. Therefore, while shortening the lateral length of the gate, we must also consider how to make a capacitor with a larger capacitance, such as increasing the area of the capacitor, reducing the effective dielectric thickness between the two electrodes, etc. However, in this embodiment, in order to maintain the channel length at an appropriate value to obtain low leakage current, a vertical transistor 120 is developed and is fabricated above the capacitor 130. Therefore, it may not only reduce the voltage of bit line BL but also may not increase the lateral area of the memory cell.

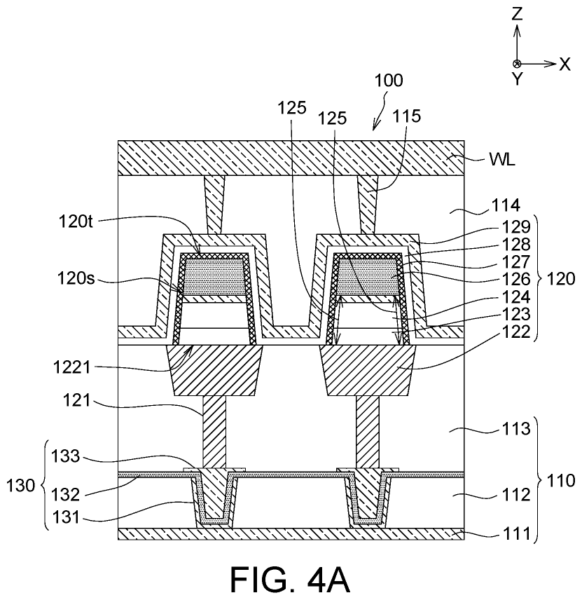

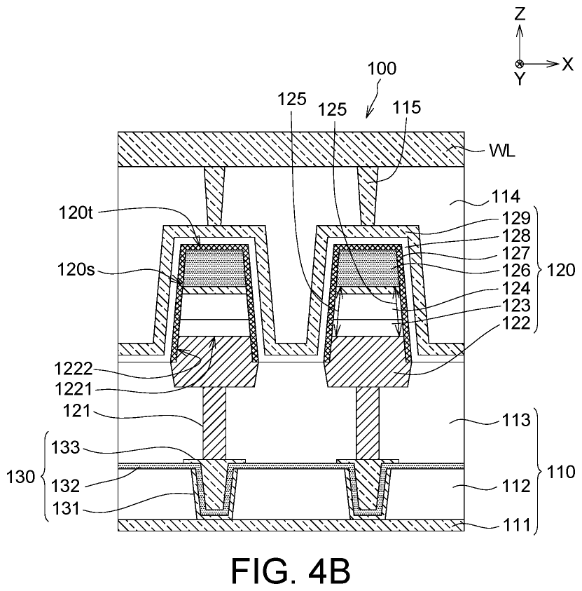

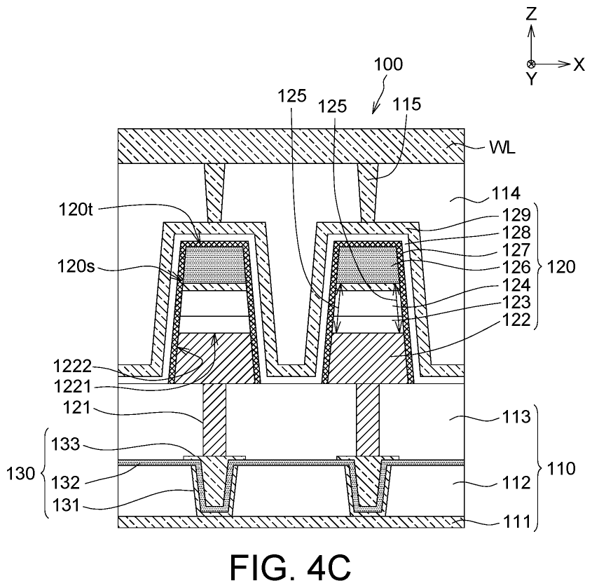

Referring to FIGS. 4A to 4C, schematic diagrams of semiconductor devices 100 according to another three embodiments of the present disclosure are respectively illustrated. In FIG. 4A, the gate 129 and the gate insulating layer 128 conformally cover the channel layer 127, and then an insulating layer 114 is formed on the gate 129. Compared with the planarized gate 129 in the above embodiment, the thickness of the gate 129 in this embodiment is relatively reduced, thereby reducing the resistance-capacitance delay (RC delay) effect of the gate 129 and making the signal transmission speed faster. In addition, after forming an insulating layer 114, a word line WL can be further formed on the insulating layer 114, and the word line WL can be electrically connected to the gate 129 through the conductive via 115. The word line WL may be a low-resistivity metal, such as copper.

In FIG. 4A, the channel layer 127, the gate insulation layer 128 and the gate 129 may extend downward along the sidewalls of the insulation layer 124 to the upper surface 1221 of the source 122. In FIGS. 4B and 4C, the channel layer 127, the gate insulating layer 128 and the gate 129 can extend downward along the sidewalls of the insulating layer 124 to the sidewalls 1222 of the source 122 to increase the contact area between the channel layer 127 and the source 122. The channel layer 127, the gate insulation layer 128 and the gate 129 extend downward from the upper surface 1221 of the source 122 to a depth that is half the thickness of the source 122 or the entire thickness of the source 122, which is not limited in this embodiment. In addition, the overlapping area between the gate 129 and the source 122 is increased, so the contact resistance from the gate 129 to the source 122 can be further reduced, and the on-resistance between the drain 126 and the source 122 can also be further reduced.

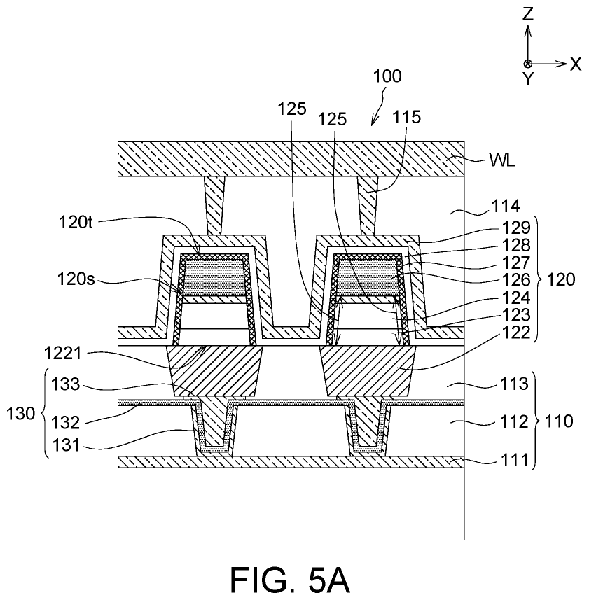

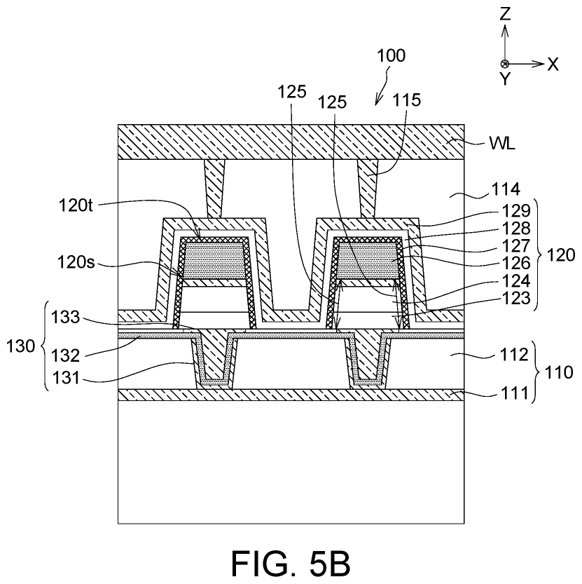

Referring to FIG. 5A and FIG. 5B, schematic diagrams of semiconductor devices 100 according to another two embodiments of the present disclosure are respectively illustrated. In FIG. 5A, the source 122 is in direct contact with the top electrode 133 of the capacitor 130, so there is no need to form a conductive via 121 between the source 122 and the capacitor 130. In FIG. 5B, the top electrode 133 of the capacitor 130 can directly serve as the source 122 of the vertical transistor 120, that is, the source 122 of the vertical transistor 120 and the top electrode 133 of the capacitor 130 are combined into one.

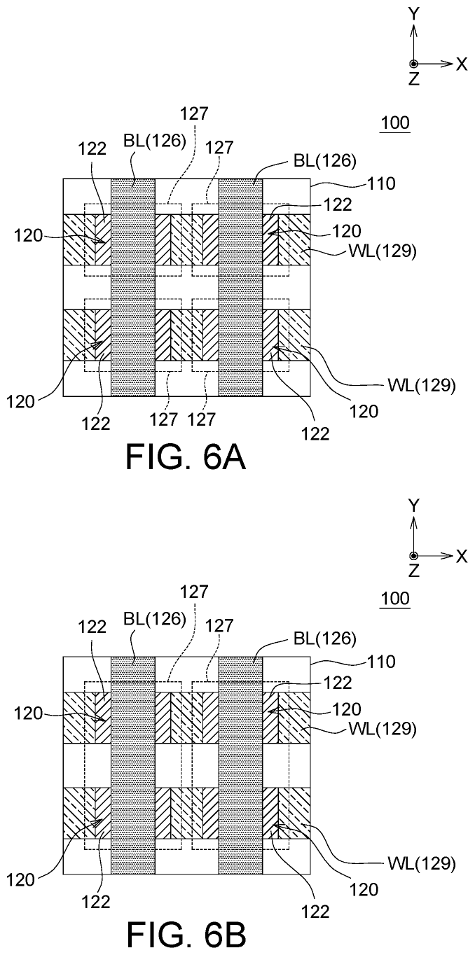

Referring to FIG. 6A and FIG. 6B, layout diagrams of semiconductor devices 100 according to two embodiments of the present disclosure are respectively illustrated. In FIGS. 6A and 6B, two bit lines BL extend along the direction Y and span across two adjacent word lines WL respectively. The intersection of each bit line BL and the corresponding word line WL forms a vertical transistor 120 and a capacitor 130 as a memory unit, such as a dynamic random access memory. In FIG. 6A, four channel layers 127 are located in respective vertical transistors 120, and the four channel layers 127 are not connected to each other. In FIG. 6B, two channel layers 127 extend along the direction Y and respectively span across two adjacent word lines WL. Therefore, the channel layers 127 of the two vertical transistors 120 located on the respective word lines WL can be connected to each other, so that the number of photomasks used to make the channel layers 127 can be reduced.

The disclosure is related to a semiconductor device and a method of manufacturing the semiconductor device, which provide a vertical transistor with channel layer at sidewalls of the vertical transistior. The vertical transistor has a longer channel length than traditional planar gate structure to reduce leakage current and increase the number of transistors per unit area. In addition, the two sidewall channels can increase the amount of driving current passing through the drain and the source of the vertical transistor to increase the reading and writing speed of the semiconductor device. The vertical transistor with long channel length and a capacitor can form a memory unit (such as DRAM) with good data retention and fast write speed without high area costs.

According to some embodiments of the disclosure, a semiconductor device is provided. The semiconductor device includes a substrate and a vertical transistor. The vertical transistor is disposed on the substrate. The vertical transistor includes an insulating layer, a source, a drain, a gate insulating layer and a gate. The source and the drain are respectively arranged below and above the insulating layer, and the gate insulating layer surrounds the insulating layer, the source and the drain. The gate covers the gate insulating layer, and the gate insulating layer separates the gate from the source and separates the gate from the drain.

According to some embodiments of the disclosure, a method of manufacturing a semiconductor device is provided. The method of manufacturing a semiconductor device includes the following steps, a stacked structure is formed on a substrate. The stacked structure is etched to form a vertical transistor, the vertical transistor including an insulating layer, a source and a drain, the source and the drain being respectively disposed below and above the insulating layer. A gate insulating layer is formed around the vertical transistor, a gate is formed to cover the gate insulating layer, and the gate insulating layer separates the gate from the source and separates the gate from the drain.

According to some embodiments of the disclosure, a semiconductor device is provided. The semiconductor device includes at least two word lines, a bit line, and a plurality of vertical transistors. The bit line corresponds to pass through the at least two word lines. The vertical transistors are respectively located at intersections of the at least two word lines and the corresponding bit line, wherein the vertical transistors comprises a channel layer at sidewalls of the vertical transistors, each of the vertical transistor comprises a source, a drain above the source, and a gate, the channel layer extends from the source to the drain and covers the top surface of the drain, and the gate surrounds the channel layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate; and
a vertical transistor disposed on a substrate, wherein the vertical transistor comprises an insulating layer, a source, a drain, a gate insulating layer and a gate, the source and the drain are respectively disposed below and above the insulating layer, the gate insulating layer surrounds the insulating layer, the source and the drain, the gate covers the gate insulating layer, and the gate insulating layer separates the gate from the source and separates the gate from the drain.

2. The semiconductor device according to claim 1, wherein the vertical transistor further comprises a channel layer surrounding sidewalls of the insulating layer and the drain and forming two sidewall channels between the source and the drain.

3. The semiconductor device according to claim 1, further comprising a capacitor disposed in the substrate, the capacitor being electrically connected to the vertical transistor.

4. The semiconductor device according to claim 3, further comprising a conductive via disposed in the substrate, the conductive via being electrically connected to the capacitor and the vertical transistor.

5. The semiconductor device according to claim 3, wherein the capacitor comprises a top electrode, a bottom electrode, and a dielectric layer, the dielectric layer being located between the top electrode and the bottom electrode.

6. The semiconductor device according to claim 5, wherein the source is in direct contact with the top electrode of the capacitor.

7. The semiconductor device according to claim 5, wherein the source and the top electrode of the capacitor are combined into one.

8. The semiconductor device according to claim 1, further comprising a bit line electrically connected to the drain.

9. The semiconductor device according to claim 1, further comprising a word line electrically connected to the gate.

10. The semiconductor device according to claim 1, wherein a number of the vertical transistor is multiple, and the vertical transistors are respectively located at intersections of two adjacent word lines and a corresponding bit line, and the vertical transistors further comprises a channel layer that spans cross the two adjacent word lines, or, each of the vertical transistors comprises a channel layer that does not span cross the two adjacent word lines.

11. A method of manufacturing a semiconductor device, comprising:
forming a stacked structure on a substrate;
etching the stacked structure to form a vertical transistor, the vertical transistor comprising an insulating layer, a source and a drain, the source and the drain being respectively disposed below and above the insulating layer;
forming a gate insulating layer around the vertical transistor; and
forming a gate to cover the gate insulating layer, and the gate insulating layer separates the gate from the source and separates the gate from the drain.

12. The method of manufacturing a semiconductor device according to claim 11, further comprising forming a channel layer, wherein the channel layer surrounds sidewalls of the insulating layer and the drain and forms two sidewall channels between the source and the drain.

13. The method of manufacturing a semiconductor device according to claim 11, further comprising forming a capacitor, the capacitor being disposed in the substrate, and the capacitor being electrically connected to the source.

14. The method of manufacturing a semiconductor device according to claim 13, further comprising forming a conductive via, the conductive via being disposed in the substrate, and the conductive via being electrically connected to the capacitor and the source.

15. The method of manufacturing a semiconductor device according to claim 13, wherein the capacitor comprises a top electrode, a bottom electrode and a dielectric layer, the dielectric layer being located between the top electrode and the bottom electrode.

16. The method of manufacturing a semiconductor device according to claim 15, wherein the source is in direct contact with the top electrode of the capacitor.

17. The method of manufacturing a semiconductor device according to claim 15, wherein the source and the top electrode of the capacitor are combined into one.

18. The method of manufacturing a semiconductor device according to claim 11, further comprising forming a bit line, the bit line being electrically connected to the drain.

19. The method of manufacturing a semiconductor device according to claim 11, further comprising forming a word line, the word line being electrically connected to the gate.

20. A semiconductor device, comprising:
at least two word lines;
a bit line corresponding to pass through the at least two word lines; and
a plurality of vertical transistors respectively located at intersections of the at least two word lines and the corresponding bit line, wherein the vertical transistors comprises a channel layer at sidewalls of the vertical transistors, each of the vertical transistor comprises a source, a drain above the source, and a gate, the channel layer extends from the source to the drain and covers the top surface of the drain, and the gate structure surrounds the channel layer.
